(19) United States
(12) Patent Application Publication
(10) Pub. No.: US 2021/0066422 A1
(43) Pub. Date: Mar. 4, 2021

(54) ARRAY SUBSTRATE AND DISPLAY PANEL

(71) Applicant: WUHAN CHINA STAR OPTOELECTRONICS SEMICONDUCTOR DISPLAY TECHNOLOGY CO., LTD., Wuhan, Hubei (CN)

(72) Inventor: Jixiang GONG, Wuhan, HUbei (CN)

(21) Appl. No.: 16/639,750

(22) PCT Filed: Dec. 5, 2019
(86) PCT No.: PCT/CN2019/123226

§ 371 Date: Feb. 18, 2020

(30) Foreign Application Priority Data
Sep. 3, 2019 (CN) 201910826546.5

(51) Int. Cl. H01L 27/32; H01L 51/52

(52) U.S. Cl. CPC H01L 27/3258; H01L 2251/301; H01L 27/3246; H01L 51/5237

(57) ABSTRACT

The present application discloses an array substrate and a display panel. The array substrate includes a second interlayer dielectric layer and a passivation layer, wherein the passivation layer is made of an inorganic material, and the second interlayer dielectric layer is made of an organic material; furthermore, the array substrate has a first deep hole and a second deep hole, and the first deep hole and the second deep hole are filled with a second interlayer dielectric layer.

### BACKGROUND OF INVENTION

The present application claims priority to Chinese patent application no. 201910826546.5 submitted to Chinese Patent Office on Sep. 3, 2019, entitled “array substrate and display panel”, the entire contents of which are incorporated herein by reference.

### FIELD OF INVENTION

The present application relates to a field of display technology, and in particular, to an array substrate and a display panel.

### DESCRIPTION OF PRIOR ART

Foldable flexible OLED displays, especially dynamically bendable flexible OLED displays, have become a new technology that various manufacturers are now competing for.

At present, introducing an organic layer structure to array layers or replacing a conventional glass substrate with a flexible PI substrate can improve the dynamic bendability, and is a common technical means to realize the flexible and bendable functions of an OLED display. However, after the organic layer structure is introduced, the process will have many difficulties that are not easy to solve, and the reliability of the device will be reduced to a certain extent.

Therefore, there is an urgent need to provide an array substrate and a display panel to solve the above problems.

### SUMMARY OF INVENTION

An object of the present application is to solve the above problems and provide an array substrate and a display panel.

In order to achieve the above object, the array substrate and the display panel described in the present application adopt the following technical solutions.

An array substrate having a base substrate, wherein the array substrate includes: a barrier layer disposed on and covering the base substrate; a buffer layer disposed between the barrier layer and an active layer and covering the barrier layer; the active layer disposed on the buffer layer; a first gate insulating layer disposed on the active layer and covering the active layer and the buffer layer; a first gate disposed on the first gate insulating layer; a second gate insulating layer disposed on the first gate and covering the first gate and the first gate insulating layer; a second gate disposed on the second gate insulating layer; a first interlayer dielectric layer disposed on the second gate and covering the second gate and the second gate insulating layer; a second interlayer dielectric layer disposed on and covering the first interlayer dielectric layer, and made of an organic material; a source and a drain disposed on the second interlayer dielectric layer and connected to the active layer through a first via hole; a passivation layer disposed on the source and drain and covering the source and drain and the second interlayer dielectric layer, and made of an inorganic material; and a planarization layer disposed on and covering the passivation layer,

wherein the array substrate includes a display area and a non-display area surrounding the display area, at least one first deep hole is provided in the display area, the first deep hole penetrates the first interlayer dielectric layer and extends to the barrier layer, and the first deep hole is filled with the second interlayer dielectric layer; and wherein at least one second deep hole is provided in the non-display area, the second deep hole penetrates the first interlayer dielectric layer and extends to the base substrate, and the second deep hole is filled with the second interlayer dielectric layer.

Further, the array substrate further includes an auxiliary electrode, which is disposed on the planarization layer, and is electrically connected to the drain through a second via hole.

Further, the array substrate further includes at least one first electrode, which is disposed on the planarization layer and is electrically connected to the auxiliary electrode.

Further, the array substrate further includes a pixel definition layer, which is disposed on the first electrode and covers the first electrode and the planarization layer, and the pixel definition layer has at least one opening, and each of the at least one opening exposes the first electrode.

Further, the array substrate further includes at least one spacer, which is disposed on the pixel definition layer.

An array substrate having a base substrate, wherein the array substrate includes: an active layer disposed on the base substrate; a first gate insulating layer disposed on the active layer and covering the active layer and the base substrate; a first gate disposed on the first gate insulating layer; a first interlayer dielectric layer disposed on the first gate and covering the first gate and the first gate insulating layer; a second interlayer dielectric layer disposed on and covering the first interlayer dielectric layer, and made of an organic material; a source and a drain disposed on the second interlayer dielectric layer and connected to the active layer through a first via hole; a passivation layer disposed on the source and drain and covering the source and drain and the second interlayer dielectric layer, and made of an inorganic material; and a planarization layer disposed on and covering the passivation layer.

Further, the array substrate further includes a barrier layer disposed on and covering the base substrate.

Further, the array substrate further includes a buffer layer disposed between the barrier layer and the active layer and covering the barrier layer.

Further, the array substrate further includes:

a second gate insulating layer disposed on the first gate and covering the first gate and the first gate insulating layer; and a second gate disposed on the second gate insulating layer.

Further, the array substrate includes a display area and a non-display area surrounding the display area, at least one first deep hole is provided in the display area, the first deep hole penetrates the first interlayer dielectric layer and extends to the barrier layer, and the first deep hole is filled with the second interlayer dielectric layer; and wherein at least one second deep hole is provided in the non-display area, the second deep hole penetrates the first interlayer dielectric layer and extends to the base substrate, and the second deep hole is filled with the second interlayer dielectric layer.

Further, the array substrate further includes an auxiliary electrode, which is disposed on the planarization layer, and is electrically connected to the drain through a second via hole.

Further, the array substrate further includes at least one first electrode, which is disposed on the planarization layer and is electrically connected to the auxiliary electrode.

Further, the array substrate further includes a pixel definition layer, which is disposed on the first electrode and covers the first electrode and the planarization layer, and the pixel definition layer has at least one opening, and each of the at least one opening exposes the first electrode.

Further, the array substrate further includes at least one spacer, which is disposed on the pixel definition layer.

A display panel including an array substrate, wherein the array substrate includes: an array substrate having a base substrate, wherein the array substrate includes: an active layer disposed on the base substrate; a first gate insulating layer disposed on the active layer and covering the active layer and the base substrate; a first gate disposed on the first gate insulating layer;

a first interlayer dielectric layer disposed on the first gate and covering the first gate and the first gate insulating layer; a second interlayer dielectric layer disposed on and covering the first interlayer dielectric layer, and made of an organic material; a source and a drain disposed on the second interlayer dielectric layer and connected to the active layer through a first via hole; a passivation layer disposed on the source and drain and covering the source and drain and the second interlayer dielectric layer, and made of an inorganic material; and a planarization layer disposed on and covering the passivation layer.

Beneficial effects of the array substrate and the display panel described in the present application are that

(1) By providing a deep hole and filling the deep hole with the second interlayer dielectric layer of organic material, the array substrate described in the present application can reduce a bending stress of the array substrate and improve bending resistance of the display device;

(2) By disposing an inorganic passivation layer between the second interlayer dielectric layer and the planarization layer, the array substrate described in the present application can increase adhesion between the layers and prevent the layers from peeling off, thereby reducing the difficulties of a manufacturing process and improving reliability of the device;

(3) By providing dual SD traces, the array substrate described in the present application can prevent a risk of short-circuit of the SD traces when the inorganic layer is bent and broken.

### BRIEF DESCRIPTION OF DRAWINGS

FIG. 1 is a schematic structural diagram of a conventional array substrate.

FIG. 2 is a schematic structural diagram of an array substrate according to the present application.

### DETAILED DESCRIPTION OF PREFERRED EMBODIMENTS

The technical solutions in the embodiments of the present application will be clearly and completely described in the following with reference to the accompanying drawings in the embodiments. It is apparent that the described embodiments are only a part of the embodiments of the present application, and not all of them. All other embodiments obtained by a person skilled in the art based on the embodiments of the present application without creative efforts are within the scope of the present application.

The terms “first”, “second”, and “third”, etc. (if present) in the specification and claims of the present disclosure are used to distinguish similar objects, and are not necessarily used to describe a particular order or prioritization. It should be understood that the objects so described are interchangeable where appropriate. Moreover, the terms “including” and “having” and “the” and any synonym thereof, are intended to cover non-exclusive inclusions.

The drawings, which are discussed below, and the various embodiments used to describe the principles of the present disclosure are intended to be illustrative only and not to limit the scope of the disclosure. Those skilled in the art will appreciate that the principles of the present disclosure may be implemented in any suitably arranged system. Exemplary embodiments will be described in detail, examples of which are illustrated in the accompanying drawings. Further, a terminal according to an exemplary embodiment will be described in detail with reference to the accompanying drawings. The same reference numerals in the drawings denote the same elements.

The terminology used in the description herein is only used to describe specific embodiments, and it is not intended to show the concept of the invention. Expressions used in the singular encompasses the plural forms of expression unless the context clearly dictates otherwise. In the description of the present invention, it is to be understood that the terms such as “including”, “having” and “containing”, are intended to be illustrative of the possibilities of the features, the numbers, the steps, the acts, or combinations thereof disclosed in the present disclosure, and it is not intended to exclude the possibility that one or more other features, numbers, steps, acts, or combinations thereof may be added. The same reference numerals in the drawings denote the same parts.

In study, the applicant of the present application found that: using a flexible PI substrate to replace the traditional glass substrate can make a display screen have the functions of flexibility and bendability; and introducing a new organic film structure into the thin film transistor can improve bending resistance of the device.

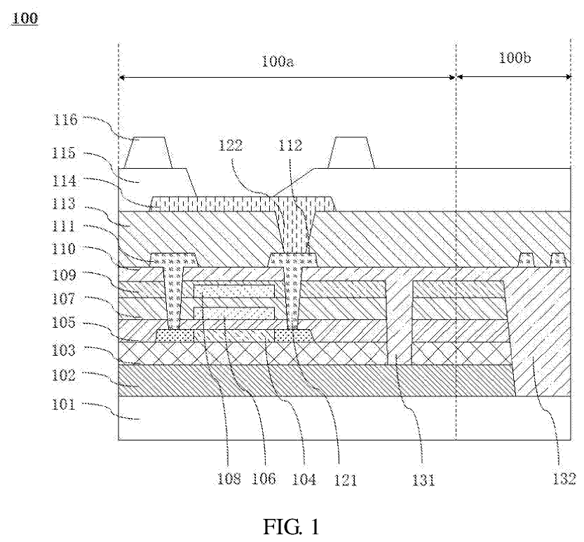

FIG. 1 is a schematic structural diagram of an existing array substrate. As shown in FIG. 1, the array substrate 100 includes a base substrate 101, a barrier layer 102, a buffer layer 103, an active layer 104 disposed on the buffer layer 103, a first gate insulating layer 105 disposed on the active layer 104, a first gate 106 disposed on the first gate insulating layer 105, a second gate insulating layer 107 disposed on the first gate 106 and covering the first gate 106 and the first gate insulating layer 105, a second gate 108 disposed on the second gate insulating layer 107, a first interlayer dielectric layer 109 disposed on the second gate 108 and covering the second gate 108 and the second gate insulating layer 107, a second interlayer dielectric layer 110 disposed on and covering the first interlayer dielectric layer 109, a source 111 and a drain 112 disposed on the second interlayer dielectric layer 110, a planarization layer 113 disposed on the source 111 and the drain 112 and covering the second interlayer dielectric layer 110, a first electrode 114 disposed on the planarization layer 113, a pixel definition layer 115 disposed on the first electrode 114 and covering the planarization layer 113, and a spacer layer 115 disposed on the pixel definition layer 116, wherein the array substrate 100 further includes a first via hole 121 and a second via hole 122, the source 111 and the drain 112 are respectively connected to the active layer 104 through the first via hole 121, and the first electrode 114 is connected to the drain 112 through the second via hole 122.

Still referring to FIG. 1, the existing array substrate 100 has a display area 100a and a non-display area 100b surrounding the display area 100a. The array substrate 100 further includes a first deep hole 131 located in the display area 100a and a second deep hole 132 located in the non-display area 100b, wherein the first deep hole 131 penetrates the first interlayer dielectric layer 109, the second gate insulating layer 107, the first gate insulating layer 105, and the buffer layer 103 and extends to the barrier layer 102, the second deep hole 132 penetrates the first interlayer dielectric layer 109, the second gate insulating layer 107, the first gate insulating layer 105, the buffer layer 103, and the barrier layer 102, and extends to the base substrate 101. In addition, the second interlayer dielectric layer 110 fills the first deep holes 131 and the second deep holes 132.

The above existing array substrate 100 can significantly improve the bending resistance of the device by providing an organic layer and a deep hole structure filled with an organic material, but at the same time, there is a problem that the adhesion between the layers becomes poor, causing a risk of peeling. The specific problem is as follows.

C—F bonds are formed on the surface of the second interlayer dielectric layer 110 after dry etching the source 111 and the drain 112, and the surface thereof is biased to be hydrophobic, while a surface of a wet film of the planarization layer 113 is biased to be hydrophilic due to its hydroxyl groups. It can be seen that there are two layers having opposite hydrophilic and hydrophobic characteristics at the interface between the second interlayer dielectric layer 110 and the planarization layer 113, and thus the adhesion between the two layers will be deteriorated, such that there is a risk of film peeling, which brings great difficulties to the manufacturing process, and also makes the reliability of the device have many risks.

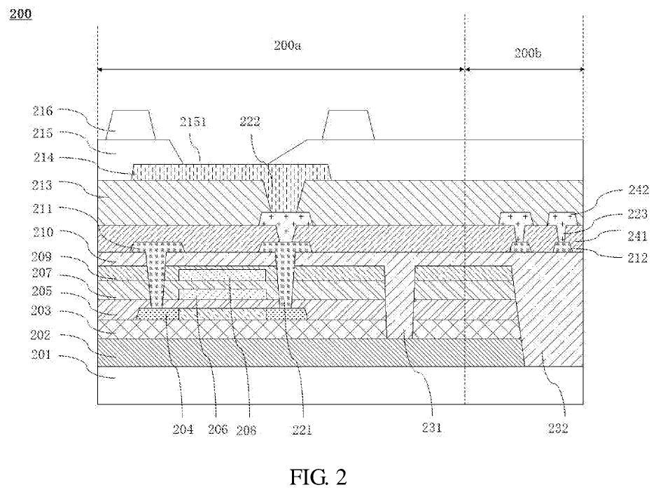

FIG. 2 is a schematic structural diagram of an array substrate according to the present application. As shown in FIG. 2, the array substrate 200 includes a base substrate 201, a barrier layer 202, a buffer layer 203, an active layer 204, a first gate insulating layer 205, a first gate 206, a second gate insulating layer 207, a second gate 208, a first interlayer dielectric layer 209, a second interlayer dielectric layer 210, a source 211, a drain 212, a planarization layer 213, and a first electrode 214, a pixel definition layer 215, a spacer layer 216, a passivation layer 241, and an auxiliary electrode 242.

The base substrate 201 is a flexible substrate, and the flexible substrate may be a PI substrate with better bending resistance and higher light transmittance.

As shown in FIG. 2, a barrier layer 202 and a buffer layer 203 are stacked on the base substrate 201 sequentially. The barrier layer 202 is disposed on the base substrate 201 and covers the base substrate 201, and is configured to prevent the active layer 204 (polysilicon active layer) to be formed later from being impacted by water vapor or impurity ions (such as excess H+, etc.) of the base substrate 201. The buffer layer 203 is disposed on the barrier layer 202 and covers the barrier layer 202. The buffer layer 203 is configured to further block the impact of the water vapor or impurity ions (such as excess H+, etc.) of the base substrate 201, and function to increase hydrogen ions of the active layer 204 to be formed later.

In a specific implementation, the barrier layer 202 or the buffer layer 203 is formed as a layered structure in a form of a single-layered or a multi-layered stack. Specifically, the barrier layer 202 or the buffer layer 203 may include at least one of a SiO2 film with good adhesion to PI or a SiNx film capable of blocking water and oxygen, and alternatively, the barrier layer 202 or the buffer layer 203 may include at least one layer of PET, PEN, polyacrylate, and/or polyimide.

As shown in FIG. 2, the active layer 204 is disposed on the buffer layer 203 and is formed with a channel region and a source contact region and a drain contact region on both sides of the channel region; the first gate insulating layer 205 is disposed on the active layer 204 and covers the active layer 204; the first gate electrode 206 is disposed on the first gate insulating layer 205; the second gate insulating layer 207 is disposed on the first gate 206 and covers the first gate 206 and the second gate insulating layer 207; the second gate 208 is disposed on the second gate insulating layer 207; the first interlayer dielectric layer 209 is disposed on the second gate 208 and covers the second gate insulating layer 207 and the second gate 208; the second interlayer dielectric layer 210 is disposed on the first interlayer dielectric layer 209 and covers the first interlayer dielectric layer 209; and the source 211 and the drain 212 are disposed on the second interlayer dielectric layer 210, and electrically connected to the source contact region and the drain contact region on the active layer 204 through the first via hole 221, respectively, wherein the first via hole 221 corresponds to the source contact region and the drain contact region of the active layer 204 and penetrates the second interlayer dielectric layer 210, the first interlayer dielectric layer 209, and second gate insulating layer 207 and the first gate insulating layer 205; the passivation layer 241 is disposed on the source 211 and the drain 212 and covers the source 211 and the drain 212 and the second interlayer dielectric layer 210, wherein the passivation layer 241 is made of an inorganic material; the auxiliary electrode 242 is disposed on the passivation layer 241, and electrically connected to the drain 212 through a third via hole 223, wherein the third via hole 223 penetrates the passivation layer 241; the planarization layer 213 is disposed on the auxiliary electrode 242 and covers the auxiliary electrode 242 and the passivation layer 241.

The first interlayer dielectric layer 209 is formed of at least one of a silicon oxide film, a silicon nitride film, a polymer, a plastic, a glass, and equivalents thereof. The second interlayer dielectric layer 210 is made of an organic material, such as, but not limited to, parylene, polyurea, hexamethyldisiloxane, or other suitable organic materials. The passivation layer 241 is made of an inorganic material, such as, but not limited to, one or more of silicon oxide (SiOx), silicon nitride (SiNx), and a metal oxide. In this embodiment, the passivation layer 241 is a SiOx layer.

As shown in FIG. 1 and FIG. 2, compared with the existing array substrate 100, by providing a passivation layer 241 between the second interlayer dielectric layer 210 and the planarization layer 213, the array substrate 200 of the present application can separate the second interlayer dielectric layer 210 from the planarization layer 213, and since the passivation layer 241 has a good adhesion to the second interlayer dielectric layer 210 and the planarization layer 213, the risk of peeling between the second interlayer dielectric layer 210 and the planarization layer 213 due to poor adhesion can be effectively prevented.

Still referring to FIG. 1 and FIG. 2, by adopting a dual SD trace structure in which the source 211 and the drain 212 are located in a level different from the auxiliary electrode 242, the traces in the peripheral area of the array substrate 200 in the present application can be located on different layers, thereby achieving the effect of a narrow bezel. On the other hand, the auxiliary electrode 242 is electrically connected to the drain 212 through a third via hole 223, which can reduce the effect of resistances of the source 211 and the drain 212. Finally, by adopting the above dual SD trace structure, the array substrate 200 described in the present application can also prevent the risk of short circuit of the SD traces caused by breaking of the inorganic layer after being bent several times.

In a specific implementation, the active layer 204 may be formed of an amorphous silicon layer, a silicon oxide layer, a metal oxide, a polysilicon layer, or an organic semiconductor material.

In a specific implementation, the first gate insulating layer 205 and the second gate insulating layer 207 are made of at least one of a silicon oxide film, a silicon nitride film, a polymer, plastic, glass, and equivalents thereof.

In consideration of conductivity, the first gate electrode 206, the second gate electrode 208, the source 211, the drain 212, and the auxiliary electrode 242 may be formed of a single material layer or a composite material layer, made of an alloy of at least one of aluminum (Al), platinum (Pt), palladium (Pd), silver (Ag), magnesium (Mg), gold (Au), nickel (Ni), neodymium (Nd), iridium (Jr), chromium (Cr), lithium (Li), calcium (Ca), molybdenum (Mo), titanium (Ti), tungsten (W), and copper (Cu), or other suitable alloys.

As shown in FIG. 2, the array substrate 200 has a display area 200a and a non-display area 200b. The array substrate 200 further includes a first deep hole 231 located in the display area 200a and a second deep hole 232 located in the non-display area 200b. The first deep hole 231 penetrates the first interlayer dielectric layer 209, the second gate insulating layer 207, the first gate insulating layer 205, and the buffer layer 203, and extends to the barrier layer 202. The second deep hole 232 penetrates the first interlayer dielectric layer 209, the second gate insulating layer 207, the first gate insulating layer 205, the buffer layer 203, and the barrier layer 202, and extends to the base substrate 201. In addition, the second interlayer dielectric layer 210 fills the first deep holes 231 and the second deep holes 232.

By providing the first deep hole 231 and the second deep hole 232, and filling the first deep hole 231 and the second deep hole 232 with the second interlayer dielectric layer 210, the array substrate 200 can reduce bending stress in the device and improve its bending resistance.

As shown in FIG. 2, at least one first electrode 214 is disposed on the planarization layer 213, and the first electrode 214 is electrically connected to the auxiliary electrode 242 through a second via hole 222. The second via hole 22 penetrates the planarization layer 213.

In a specific implementation, the first electrode 214 may be a transparent (transflective) electrode, a reflective electrode, or a metal electrode. When the first electrode 214 is formed as a transparent (transflective) electrode, it may be made of a mixture of one or more transparent electrode materials selected from indium tin oxide (ITO), indium zinc oxide (IZO), zinc oxide (ZnO), indium oxide (In2O3), indium gallium oxide (IGO) or alumina zinc (AZO).

When the first electrode 214 is formed as a reflective electrode, the reflective electrode layer may be formed by stacking the reflective electrode and the auxiliary layer, wherein the reflective electrode is made of a mixture of any one or more of silver (Ag), magnesium (Mg), aluminum (Al), platinum (Pt), palladium (Pd), gold (Au), nickel (Ni), neodymium (Nd), iridium (Jr), chromium (Cr), and the auxiliary layer is made a transparent electrode material selected from indium tin oxide (ITO), indium zinc oxide (IZO), zinc oxide (ZnO), indium oxide (In2O3), and the like. The structure and material of the first electrode 214 are not limited thereto and may be changed.

When the first electrode 214 is formed of metal electrode, it may be made of a mixture of any one or more of silver (Ag), magnesium (Mg), aluminum (Al), platinum (Pt), palladium (Pd), gold (Au), nickel (Ni), neodymium (one or more of metal electrode materials such as Nd), iridium (Jr), and chromium (Cr).

As shown in FIG. 2, a pixel definition layer 215 is provided on the first electrode 214. The pixel definition layer 215 covers the first electrode 214 and the planarization layer 213. The pixel definition layer 215 has at least one opening 2151, and each of the at least one opening 2151 correspondingly exposes a first electrode 214. The pixel definition layer 215 is configured to define sub-pixels.

As shown in FIG. 2, the spacer layer 216 is located on the planarization layer 215 away from the first electrode 214. Specifically, the spacer layer 216 includes a plurality of supports disposed at intervals, and the supports are disposed in a non-opening area of the pixel definition layer 215. The spacer layer 216 can serve as a process mask for the light-emitting layer during evaporation coating. In a specific implementation, the spacer layer 216 may be an organic layer, and may also be made of a light-sensitive material, such as a photoresist.

By providing the first deep hole 231 and the second deep hole 232, and filling the first deep hole 231 and the second deep hole 232 with the second interlayer dielectric layer 210, the array substrate 200 in the present application can reduce the bending stress of each layer and improve the bending resistance of the display device; by disposing the inorganic passivation layer 241 between the second interlayer dielectric layer 210 and the planarization layer 213, adhesion between the layers is increased, thereby preventing the layers from peeling;

by adopting a dual SD trace structure in which the source 211 and the drain 212 are located in a level different from the auxiliary electrode 242, functions of reducing resistance of the source 211 and the drain 212, preventing short circuit of SD traces, and realizing a narrow bezel can be achieved.

The above is only the preferred implementation of the present application. It should be noted that, for those of ordinary skill in the art, without departing from the principles of the present application, several improvements and retouches can be made, and these improvements and retouches should also be considered the scope of protection of this application.

What is claimed is:

1. An array substrate having a base substrate, wherein the array substrate comprises:
a barrier layer disposed on and covering the base substrate;
a buffer layer disposed between the barrier layer and an active layer and covering the barrier layer;
the active layer disposed on the buffer layer;
a first gate insulating layer disposed on the active layer and covering the active layer and the buffer layer;
a first gate disposed on the first gate insulating layer;
a second gate insulating layer disposed on the first gate and covering the first gate and the first gate insulating layer;
a second gate disposed on the second gate insulating layer;
a first interlayer dielectric layer disposed on the second gate and covering the second gate and the second gate insulating layer;
a second interlayer dielectric layer disposed on and covering the first interlayer dielectric layer, and made of an organic material;
a source and a drain disposed on the second interlayer dielectric layer and connected to the active layer through a first via hole;
a passivation layer disposed on the source and drain and covering the source and drain and the second interlayer dielectric layer, and made of an inorganic material; and
a planarization layer disposed on and covering the passivation layer,
wherein the array substrate comprises a display area and a non-display area surrounding the display area, at least one first deep hole is provided in the display area, the first deep hole penetrates the first interlayer dielectric layer and extends to the barrier layer, and the first deep hole is filled with the second interlayer dielectric layer; and
wherein at least one second deep hole is provided in the non-display area, the second deep hole penetrates the first interlayer dielectric layer and extends to the base substrate, and the second deep hole is filled with the second interlayer dielectric layer.

2. The array substrate according to claim 1, wherein the array substrate further comprises an auxiliary electrode, which is disposed on the planarization layer, and is electrically connected to the drain through a second via hole.

3. The array substrate according to claim 2, wherein the array substrate further comprises at least one first electrode, which is disposed on the planarization layer and is electrically connected to the auxiliary electrode.

4. The array substrate according to claim 3, wherein the array substrate further comprises a pixel definition layer, which is disposed on the first electrode and covers the first electrode and the planarization layer, and the pixel definition layer has at least one opening, and each of the at least one opening exposes the first electrode.

5. The array substrate according to claim 4, wherein the array substrate further comprises at least one spacer, which is disposed on the pixel definition layer.

6. An array substrate having a base substrate, wherein the array substrate comprises:
an active layer disposed on the base substrate;
a first gate insulating layer disposed on the active layer and covering the active layer and the base substrate;
a first gate disposed on the first gate insulating layer;
a first interlayer dielectric layer disposed on the first gate and covering the first gate and the first gate insulating layer;
a second interlayer dielectric layer disposed on and covering the first interlayer dielectric layer, and made of an organic material;
a source and a drain disposed on the second interlayer dielectric layer and connected to the active layer through a first via hole;
a passivation layer disposed on the source and drain and covering the source and drain and the second interlayer dielectric layer, and made of an inorganic material; and
a planarization layer disposed on and covering the passivation layer.

7. The array substrate according to claim 6, wherein the array substrate further comprises a barrier layer disposed on and covering the base substrate.

8. The array substrate according to claim 7, wherein the array substrate further comprises a buffer layer disposed between the barrier layer and the active layer and covering the barrier layer.

9. The array substrate according to claim 7, wherein the array substrate further comprises:
a second gate insulating layer disposed on the first gate and covering the first gate and the first gate insulating layer; and
a second gate disposed on the second gate insulating layer.

10. The array substrate according to claim 7, wherein the array substrate comprises a display area and a non-display area surrounding the display area, at least one first deep hole is provided in the display area, the first deep hole penetrates the first interlayer dielectric layer and extends to the barrier layer, and the first deep hole is filled with the second interlayer dielectric layer; and
wherein at least one second deep hole is provided in the non-display area, the second deep hole penetrates the first interlayer dielectric layer and extends to the base substrate, and the second deep hole is filled with the second interlayer dielectric layer.

11. The array substrate according to claim 6, wherein the array substrate further comprises an auxiliary electrode, which is disposed on the planarization layer, and is electrically connected to the drain through a second via hole.

12. The array substrate according to claim 11, wherein the array substrate further comprises at least one first electrode, which is disposed on the planarization layer and is electrically connected to the auxiliary electrode.

13. The array substrate according to claim 12, wherein the array substrate further comprises a pixel definition layer, which is disposed on the first electrode and covers the first electrode and the planarization layer, and the pixel definition layer has at least one opening, and each of the at least one opening exposes the first electrode.

14. The array substrate according to claim 13, wherein the array substrate further comprises at least one spacer, which is disposed on the pixel definition layer.

15. A display panel comprising an array substrate, wherein the array substrate comprises:
an array substrate having a base substrate, wherein the array substrate comprises:
an active layer disposed on the base substrate;
a first gate insulating layer disposed on the active layer and covering the active layer and the base substrate;
a first gate disposed on the first gate insulating layer;
a first interlayer dielectric layer disposed on the first gate and covering the first gate and the first gate insulating layer;
a second interlayer dielectric layer disposed on and covering the first interlayer dielectric layer, and made of an organic material;
a source and a drain disposed on the second interlayer dielectric layer and connected to the active layer through a first via hole;
a passivation layer disposed on the source and drain and covering the source and drain and the second interlayer dielectric layer, and made of an inorganic material; and
a planarization layer disposed on and covering the passivation layer.
